(19) United States
(12) Patent Application Publication
(10) Pub. No.: US 2019/0370177 A1
(43) Pub. Date: Dec. 5, 2019

(54) HARDWARE-ASSISTED PAGE ACCESS TRACKING

(71) Applicant: Nutanix, Inc., San Jose, CA (US)

(72) Inventor: Jan Ralf Alexander OLDERDISSEN, Herrenberg (DE)

(73) Assignee: Nutanix, Inc., San Jose, CA (US)

(21) Appl. No.: 15/891,751

(22) Filed: Feb. 8, 2018

(51) Int. Cl. G06F 12/0871; G06F 12/0882; G06F 12/0891; G06F 12/122; G06F 12/123

(52) U.S. Cl. CPC G06F 12/0871; G06F 12/0882; G11C 15/046; G06F 12/122; G06F 12/123; G06F 12/0891

(57) ABSTRACT

A memory subsystem is interfaced to a CPU through memory controllers. The memory subsystem is composed of a first tier of first memory devices having a first set of performance characteristics and a second tier of second memory devices having a second set of performance characteristics that are different from the first set of performance characteristics. A content addressable memory stores the memory addresses that are used to access the first memory devices and/or second memory devices. Logic is provided that updates one or more registers or memory structures to count the frequency and timing of occurrences of the memory address accesses. Both the content addressable memory and logic can be implemented on the same semiconductor substrate. The content addressable memory may be interfaced to a random access memory that stores counters. The logic may comprise one or more state machines implemented on the same semiconductor substrate as the CPU.

### FIELD

This disclosure relates to computing systems, and more particularly to techniques for hardware-assisted page access tracking in virtual memory computing systems.

### BACKGROUND

Modern computing systems support virtual memory concepts to facilitate scaling in various dimensions. For example, a virtual memory system might be implemented so as to allocate a certain virtual memory space to each of a plurality of computing entities (e.g., computing processes, computing tasks, virtual machines, etc.). Such allocation and ongoing management of the virtual memory space facilitates multi-processing by the computing entities. Often, the total virtual memory space allocated to such computing entities far exceeds the physical memory available to the computing system. When the allocated virtual memory space exceeds the physical memory space, some technique is needed to prioritize access to the physical memory.

One such technique involves swapping of pages (e.g., 4 kB memory spaces) over multiple tiers of memory devices that each have a respective performance-cost tradeoff characteristic. For example, a highest tiered memory device might be a random access memory (RAM) device (e.g., a DDR4 DIMM device), whereas a next highest tiered memory device might be a random access persistent memory (RAPM) device (e.g., an Intel Xpoint device). Lower tiered devices might include NVMe devices, SSDs, or even HDDs. Such paging or page swapping techniques, when supported by an operating system, allows the computing system to operate beyond the limits of the available physical random access memory without crashing or rejecting tasks or processes that, individually or in aggregate, demand more memory space than is provided by the physical random access memory of the system.

RAPM devices in a multi-tiered memory system can be addressable in a manner that is characteristic of a RAM device. Specifically, RAPM devices can hold instructions that can be directly executed by a CPU in the same manner as a RAM device (e.g., via random access instruction fetches). When an RAPM device is used as a swap device, a page of memory that is swapped out from a RAM device to the RAPM device can be accessed directly by the CPU at any random address of the RAPM, rather than having to swap the page back into a RAM device.

Even given the longer access latencies of the RAPM device as compared to that of the RAM device, a certain level of such direct accesses can remain more economical (e.g., in overall latency terms) than the alternative of swapping the page back to the RAM device. However, as the number and/or frequency of direct accesses by the CPU increases (e.g., as the number of computing entities in the system increases), the longer latencies of the RAPM device will accumulate so as to favor swapping the accessed page or pages back from the RAPM device to the RAM device rather than continuing to access the frequently-accessed pages at the RAPM device.

Unfortunately, keeping track of the number and/or frequency of accesses to pages on an RAPM device is computationally intensive, at least in that accesses to be counted or otherwise kept track of happen at CPU memory cycle speeds (e.g., a few nanoseconds per access). There is no operating system or “kernel” or other facility that relies on hand-coded or compiled software that can keep up with tracking such accesses in real-time. Thus, pages of memory that had been moved from RAM devices to RAPM devices tend to stay in the RAPM devices—even though doing so often incurs the aforementioned higher latencies.

What is needed is a way to track random access device accesses in real-time so that frequently accessed pages can be subjected to memory paging tracking so as to determine when to move highly accessed pages from one memory tier to another memory tier (e.g., from a RAPM device to a RAM device).

### SUMMARY

The present disclosure describes techniques used in systems, methods, and in computer program products for hardware-assisted page access tracking, which techniques advance the relevant technologies to address technological issues with legacy approaches. More specifically, the present disclosure describes techniques used in systems, methods, and in computer program products for hardware-assisted page access tracking in multi-tiered random access memory systems. Certain embodiments are directed to technological solutions for implementing a page access detector in a CPU of a computing system to accumulate page access statistics corresponding to a plurality of random access memory spaces of a multi-tiered memory system.

The disclosed embodiments modify and improve over legacy approaches. In particular, the herein-disclosed techniques provide technical solutions that address the technical problems attendant to accurately and efficiently tracking swap space accesses. Such technical solutions relate to improvements in computer functionality. Various applications of the herein-disclosed improvements in computer functionality serve to reduce the demand for computer memory, reduce the demand for computer processing power, reduce network bandwidth use, and reduce the demand for inter-component communication. Some embodiments disclosed herein use techniques to improve the functioning of multiple systems within the disclosed environments, and some embodiments advance peripheral technical fields as well. As one specific example, use of the disclosed techniques and devices within the shown environments as depicted in the figures provide advances in the technical field of high performance computing as well as advances in various technical fields related to computer processor and memory system interfaces.

Further details of aspects, objectives, and advantages of the technological embodiments are described herein and in the drawings and claims.

### BRIEF DESCRIPTION OF THE DRAWINGS

The drawings described below are for illustration purposes only. The drawings are not intended to limit the scope of the present disclosure.

FIG. 1A illustrates a computing environment in which embodiments of the present disclosure can be implemented.

FIG. 1B is a schematic showing hardware components of a CAM interconnected logic to implement fast, hardware-assisted page access tracking for management of the contents of a multi-tiered memory system, according to some embodiments.

FIG. 2A and FIG. 2B depict hardware-assisted page access tracking techniques as implemented in systems that facilitate hardware-assisted page access tracking in multi-tiered random access memory systems, according to an embodiment.

FIG. 3 presents a block diagram of a system for hardware-assisted page access tracking in multi-tiered random access memory systems, according to an embodiment.

FIG. 4A depicts a page access statistics eviction technique as implemented in systems that facilitate hardware-assisted page access tracking in multi-tiered random access memory systems, according to an embodiment.

FIG. 4B depicts a page access statistics flush technique as implemented in systems that facilitate hardware-assisted page access tracking in multi-tiered random access memory systems, according to an embodiment.

FIG. 5 illustrates a paging technique as implemented in systems that facilitate hardware-assisted page access tracking in multi-tiered random access memory systems, according to an embodiment.

FIG. 6 depicts system components as arrangements of computing modules that are interconnected so as to implement certain of the herein-disclosed embodiments.

FIG. 7 presents a block diagram of computer system architectures having components suitable for implementing embodiments of the present disclosure, and/or for use in the herein-described environments.

### DETAILED DESCRIPTION

Embodiments in accordance with the present disclosure address the problem of accurately and efficiently tracking memory page accesses. Some embodiments are directed to approaches for implementing a page access detector in a CPU of a computing system to accumulate page access statistics corresponding to a plurality of random access memory spaces of a multi-tiered memory system. The accompanying figures and discussions herein present example environments, systems, apparatus, methods, and computer program products for hardware-assisted page access tracking in multi-tiered random access memory systems.

### Overview

Disclosed herein are techniques for implementing a page access detector in a CPU of a computing system to accumulate page access statistics corresponding to the random access memory space of a multi-tiered memory system. In certain embodiments, the page access detector comprises a content-addressable memory (CAM) that stores an access count corresponding to the pages accessed by the CPU. Certain logic at the page access detector facilitates sorting of the CAM and/or transfer of certain portions of the CAM to an access log. The access log can be accessed by an operating system at the computing system to perform certain paging operations over the multi-tiered memory system. In certain embodiments, the multi-tiered memory system comprises at least one RAPM device. In certain embodiments, the logic of the page access detector implements an LRU algorithm. In certain embodiments, the content of the CAM is flushed to the access log according to a schedule. In certain embodiments, the access log is stored at a RAM device. In certain embodiments, the access log is implemented as a ring buffer. In certain embodiments, the multi-tiered memory system comprises two different types of

### Definitions and Use of Figures

Some of the terms used in this description are defined below for easy reference. The presented terms and their respective definitions are not rigidly restricted to these definitions—a term may be further defined by the term's use within this disclosure. The term “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion. As used in this application and the appended claims, the term “or” is intended to mean an inclusive “or” rather than an exclusive “or”. That is, unless specified otherwise, or is clear from the context, “X employs A or B” is intended to mean any of the natural inclusive permutations. That is, if X employs A, X employs B, or X employs both A and B, then “X employs A or B” is satisfied under any of the foregoing instances. As used herein, at least one of A or B means at least one of A, or at least one of B, or at least one of both A and B. In other words, this phrase is disjunctive. The articles “a” and “an” as used in this application and the appended claims should generally be construed to mean “one or more” unless specified otherwise or is clear from the context to be directed to a singular form.

Various embodiments are described herein with reference to the figures. It should be noted that the figures are not necessarily drawn to scale and that elements of similar structures or functions are sometimes represented by like reference characters throughout the figures. It should also be noted that the figures are only intended to facilitate the description of the disclosed embodiments—they are not representative of an exhaustive treatment of all possible embodiments, and they are not intended to impute any limitation as to the scope of the claims. In addition, an illustrated embodiment need not portray all aspects or advantages of usage in any particular environment.

An aspect or an advantage described in conjunction with a particular embodiment is not necessarily limited to that embodiment and can be practiced in any other embodiments even if not so illustrated. References throughout this specification to “some embodiments” or “other embodiments” refer to a particular feature, structure, material or characteristic described in connection with the embodiments as being included in at least one embodiment. Thus, the appearance of the phrases “in some embodiments” or “in other embodiments” in various places throughout this specification are not necessarily referring to the same embodiment or embodiments. The disclosed embodiments are not intended to be limiting of the claims.

### Descriptions of Example Embodiments

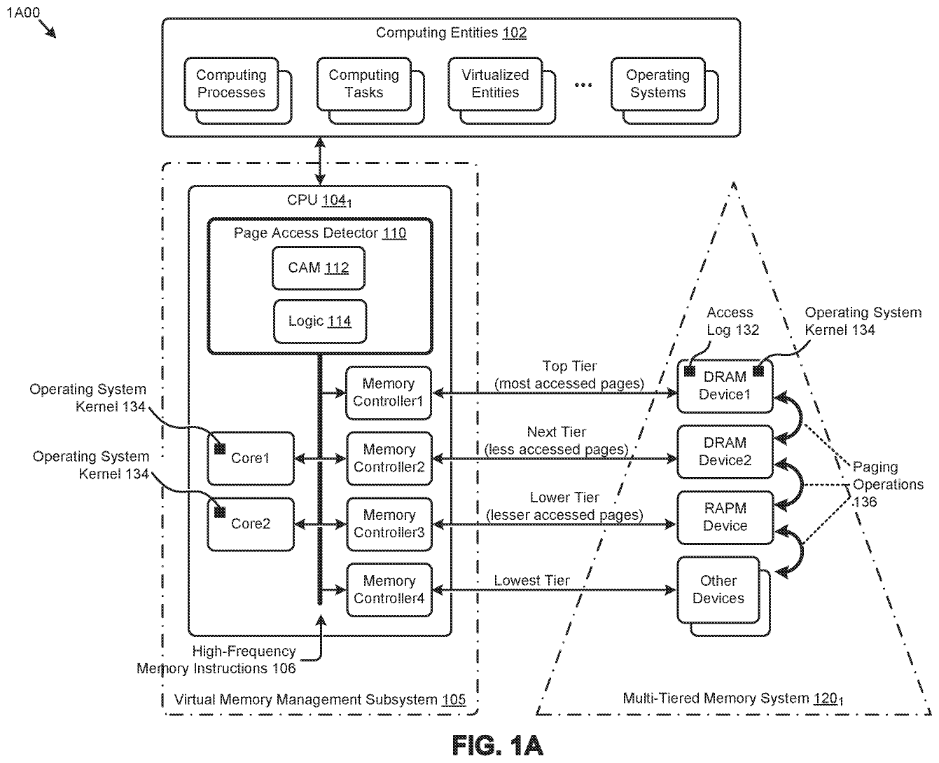

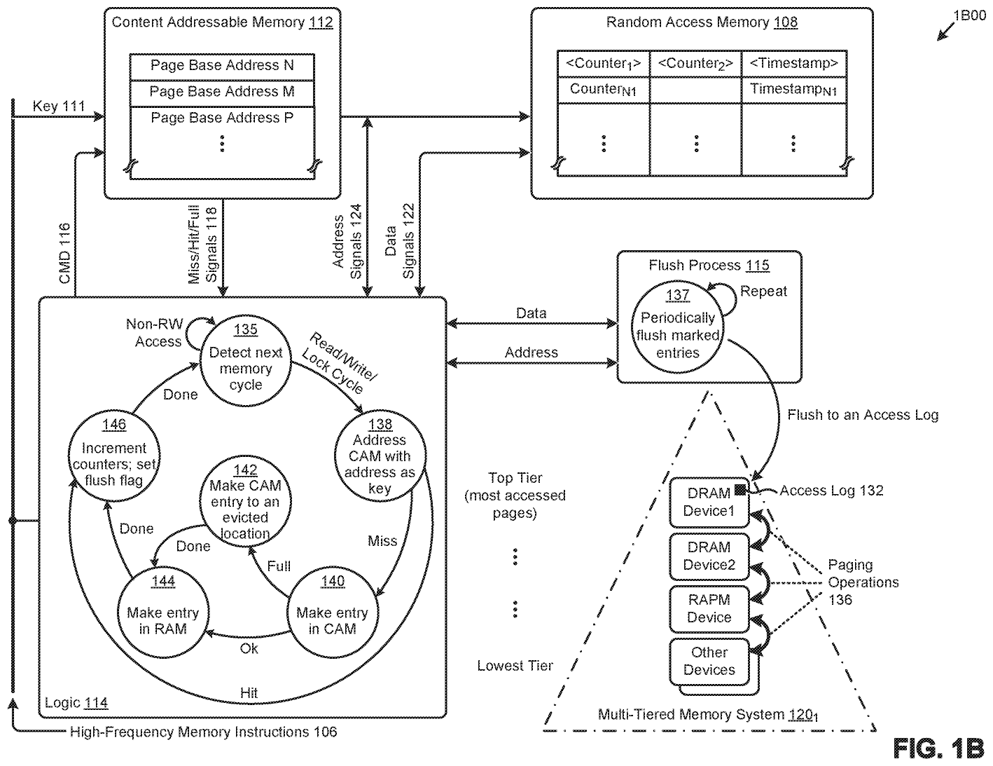

FIG. 1A illustrates a computing environment 1A00 in which embodiments of the present disclosure can be implemented. As an option, one or more variations of computing environment 1A00 or any aspect thereof may be implemented in the context of the architecture and functionality of the embodiments described herein.

FIG. 1A illustrates one aspect pertaining to implementing a page access detector in a CPU of a computing system to accumulate page access statistics corresponding to a plurality of random access memory spaces of a multi-tiered memory system. Specifically, the figure is presented to illustrate a hardware-assisted technique that addresses the problem of accurately and efficiently tracking page accesses in modern computing systems.

The figure shows how a content addressable memory (CAM) and logic can be combined so as to make fast decisions about what paging operations should be performed. More specifically, and as shown, a page access detector works in combination with an operating system kernel and a plurality of memory controllers to accomplish page-in and page-out operations.

In this embodiment, computing environment 1A00 comprises a plurality of computing entities 102 (e.g., processes, tasks, virtualized entities, etc.) that rely on a CPU 104₁ to perform certain computing operations. The CPU 104₁ comprises multiple cores (e.g., “Core1” and “Core2”) and multiple memory controllers (e.g., “Memory Controller1”, “Memory Controller2”, “Memory Controller3”, and “Memory Controller4”) to carry out the operations invoked by the computing entities 102. In some cases, such operations are facilitated by high-frequency memory instructions 106 issued by the CPU cores to the memory controllers which, in turn, interface with storage devices in a multi-tiered memory system 120₁ to carry out the instructions. As shown, the multi-tiered memory system 120₁ in computing environment 1A00 comprises a first type of dynamic random access memory (DRAM) device (e.g., “DRAM Device1” having a first access speed), a second type of DRAM device (e.g., “DRAM Device2” having a second access speed), an RAPM device, and other memory devices (e.g., slower devices having other access speeds).

Such a mix of memory devices might be selected for their respective performance-cost tradeoff characteristics. For example, “DRAM device1” might have the highest performance (e.g., shortest access latency) and highest cost, whereas the memory mapped devices might have the lowest performance (e.g., longest access latency) and lowest cost. In this case, “DRAM Device1” might be configured to store the most accessed pages and the memory mapped devices might be configured to store the least accessed pages to achieve certain performance and cost objectives. The foregoing configuration relies on certain of the paging operations 136 to appropriately place the pages over the multi-tiered memory system 120₁ so as to achieve those performance and cost objectives. As earlier mentioned, however, keeping track of the number and/or frequency of accesses to pages on a DRAM device or an RAPM device is computationally intensive, at least in that the high-frequency memory instructions 106 (e.g., READ and/or WRITE instructions) to be tracked happen at CPU memory cycle speeds (e.g., a few nanoseconds per occurrence of a memory access).

In some cases, the high-frequency memory instructions 106 include SNOOP instructions. In certain embodiments, the memory controllers (e.g., “Memory Controller1”, “Memory Controller2”, “Memory Controller3”, and “Memory Controller4”) are configured to carry out the operations pertaining to SNOOP instructions. Strictly as illustrative examples, in architectures where a memory cache is implemented between the high-frequency memory instructions 106 and the page access detector 110, the page access detector counts memory access operations that the memory controllers carry out over the devices within the multi-tiered memory system, rather than counting cache memory accesses. Such memory access operation counts are strongly correlated to operations over the devices within the multi-tiered memory system 120₁.

In other architectures where the page access detector 110 is implemented between the high-frequency memory instructions 106 and the memory cache, the page access detector counts cache memory access operations. Such cache memory access operation counts are strongly correlated to hot spots in the cache, which may or may not be strongly correlated to operations over the devices within the multi-tiered memory system.

In some cases, the high-frequency memory instructions 106 include LOCK and UNLOCK instructions over particular addresses. The page access detector 110 can count memory accesses to particular LOCK and UNLOCK addresses, and such counts can be used to identify contention for locks. The particular LOCK and UNLOCK counts can be used for thread management. As an example, an operating system might monitor particular LOCK and UNLOCK counts pertaining to particular LOCK and UNLOCK addresses, use the counts to form patterns and/or classify the uses of the LOCK and UNLOCK instructions, evaluate the patterns or classifications of lock contention across multiple cores of a CPU, and then decide to move certain threads that use the same LOCK and UNLOCK addresses onto a different core so as to reduce the quantity of contention events experienced by a given core.

Continuing the discussion of techniques for managing the multi-tiered memory system 120₁, the herein disclosed techniques address issues attendant to accurately and efficiently tracking memory page accesses by implementing a page access detector 110 in CPU 104₁ to accumulate page access statistics corresponding to the random access memory space of multi-tiered memory system 120₁. In the shown embodiment, the page access detector 110 comprises a content-addressable memory (e.g., CAM 112) that stores page access statistics (e.g., one or more access counts) corresponding to the pages accessed by CPU 104₁. Logic 114 at page access detector 110 facilitates sorting of the data records in CAM 112 and/or transfer of certain data records of CAM 112 to an access log 132. The access log 132 can be accessed by an operating system kernel 134 to perform the paging operations 136 over the multi-tiered memory system 120₁.

One embodiment of a technique for page access tracking is implemented in a virtual memory management subsystem 105 using a page access detector 110. Such an embodiment is disclosed in further detail as shown and described in FIG. 1B.

FIG. 1B is a schematic 1B00 showing hardware components of a CAM interconnected logic to implement fast, hardware-assisted page access tracking for management of the contents of a multi-tiered memory system.

When performing hardware-assisted page access tracking, some means for quickly counting the number of accesses to a page are needed. One way to do so, even at memory bus speeds, is to use a content addressable memory. Entries (e.g., keys) that are the base address of a page are written to the CAM as they occur on the memory bus. Counters comprise read counters, write counters, and transfer counters. The read counters are incremented each time a page is accessed through a READ memory cycle. The write counters are incremented each time a page is accessed through a WRITE memory cycle. The transfer counters are incremented to correspond to the volume (e.g., number of bytes) that are transferred through a WRITE memory cycle or a READ memory cycle over a particular page. Accordingly, the counters and any corresponding timestamps provide an indication of the frequency and timing of accesses to a particular page of memory.

As shown, the CAM accepts a key 111 (e.g., the base address of a page) as an input, and outputs a set of address signals 124. The address is the address of the CAM that corresponds to (e.g., matches) the key, which address is then used to access a random access memory 108 via the address signals 124 to read the data at that address via data signals 122. As shown, the data of the random access memory can include memory structures that hold multiple counters and/or one or more timestamps. The memory structures comprising such counters and timestamps are continuously updated such that for any given page for which its base address is stored in the CAM, an up-to-date indication of the frequency and timing of accesses can be taken from the memory structures stored in the random access memory 108.

For example, when a page base address for page “N” is entered into the CAM (e.g., when the signal CMD 116 asserts a WRITE command), it is stored in a CAM row at a particular address. That address is output when the base address for page “N” is presented on the CAM input shown as key 111. The output address is in turn used to address into the random access memory 108 so as to read the values of the memory structures at that random access memory address. The width of the random access memory 108 memory structures can be sized to be wide enough to contain as many counters and/or timestamps as are needed, each with as much dynamic range as needed.

When an address is (e.g., a base address for a page) is presented on the CAM input shown as key 111, the CAM will assert the miss/hit/full signal in a manner so as to indicate if there is no such entry in the CAM (e.g., a “miss”) or, in the event that there is such an entry in the CAM (e.g., a “hit”), the CAM will assert the miss/hit/full signal in a manner so as to indicate that the entry was found. In some situations, such as can occur in the case of a WRITE command, it is possible that there is no available entry in the CAM to be able to store the address to be written. In such cases, the miss/hit/full signal is asserted in a manner to indicate that the CAM is “full”.

Signals to/from the content addressable memory as well as signals to/from the random access memory can be interfaced with logic 114, as shown. Logic 114 implements a state machine that is used to perform fast hardware-assisted page access tracking. At state 135, the logic detects a next memory cycle. In most cases, the detected memory cycle type is a READ or a WRITE or a LOCK command, however in some cases, the detected memory cycle type is not a READ or a WRITE or a LOCK command, and thus can be ignored by logic 114. Otherwise, in cases of a READ/WRITE/LOCK cycle, the base address of a page of data is used as a key input for the CAM. In some checks that occurs during state 138, it might be determined (e.g., by the CAM itself) that a key (e.g., a page base address) is a “hit”; thus, the hit signal is asserted, which causes a state transition to state 146 to increment counters and/or update timestamps and/or set a flush flag by executing one or more memory cycles (e.g., READ/MODIFY/WRITE cycles) to access the random access memory 108. Once the random access memory has been accessed, the state can re-enter into state 135 to wait for a next detected command cycle.

It might happen that the time it takes to progress from state 135 through other states and then back to state 135 is longer than the cycle time of one or more of the high-frequency memory instructions. In such a case, a page access might be missed. Such an occurrence is expected, and does not significantly impact the ability of the system to identify “hot” pages. However, to reduce the likelihood that a page access might be missed, the CAM 112, the random access memory 108, and the logic 114 might be implemented on the same silicon substrate. More particularly, in some embodiments, the CAM 112, the random access memory 108, and the logic 114 are all implemented on the same silicon substrate as the CPU 104₁ of FIG. 1A.

In some cases, when the base address of a page of data is used as a key input for the CAM, the CAM asserts the miss/hit/full signals 118 with a “miss” indication. This indicates that an entry is to be made into the CAM and that a corresponding entry into random access memory 108 is to be made. Accordingly, state 138 transitions to state 140 (e.g., to make an entry in the CAM) and then to state 144 (e.g., to make a corresponding entry in random access memory 108). During processing in state 140, specifically during performance of CAM cycles to add the entry, it can happen that the CAM is already full, in which case the CAM asserts the miss/hit/full signals 118 with a “full” indication. This causes a transition from state 140 to state 142, which in turn makes a determination as to what entry to evict. Once a free slot in the CAM becomes available due to the eviction, the entry is made into the CAM and processing proceeds to state 144 so as to store/initialize any corresponding counters and/or timestamps in the random access memory 108.

Any known technique can be used choose an entry to evict so as to make room for a new entry. In one case, a first-in-first-out (FIFO) or shift register is used to keep track of recently accessed pages. When room is needed to be able to enter a new address that is at least potentially a candidate for a “hot” page, the FIFO or shift register is consulted, and the oldest candidate is evicted from both the FIFO (or shift register) and the CAM. State 144 proceeds to state 146. In state 146, the counters of the random access memory 108 are read, incremented, and written back to the random access memory. A flush flag that is stored in the random access memory 108 is set to indicate the occurrence of activity since the last flush.

State machine processing within logic 114 proceeds continuously and asynchronously with other hardware processing. At any point in time, some or all of the contents of the random access memory 108 can be flushed so as to populate an access log. In the embodiment shown, a flush process 115 (e.g., another state machine 137) operates a timer or counter. When a time period expires, or when the counter reaches a pre-determined value, then the flush process 115 accesses random access memory 108 and flushes the entries that are marked with their flush flag set. Once an entry has been flushed, its flush flag can be cleared.

As shown, the flush process writes entries into access log 132. An operating system function (e.g., a function of the operating system kernel) processes the access log to determine what, if any, paging operations 136 are to be performed over the multi-tiered memory system 120₁.

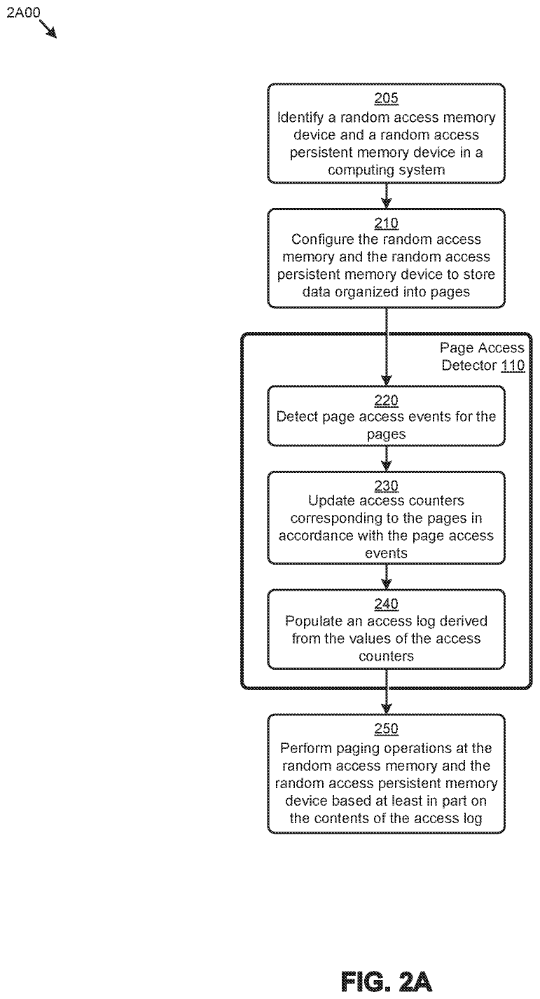

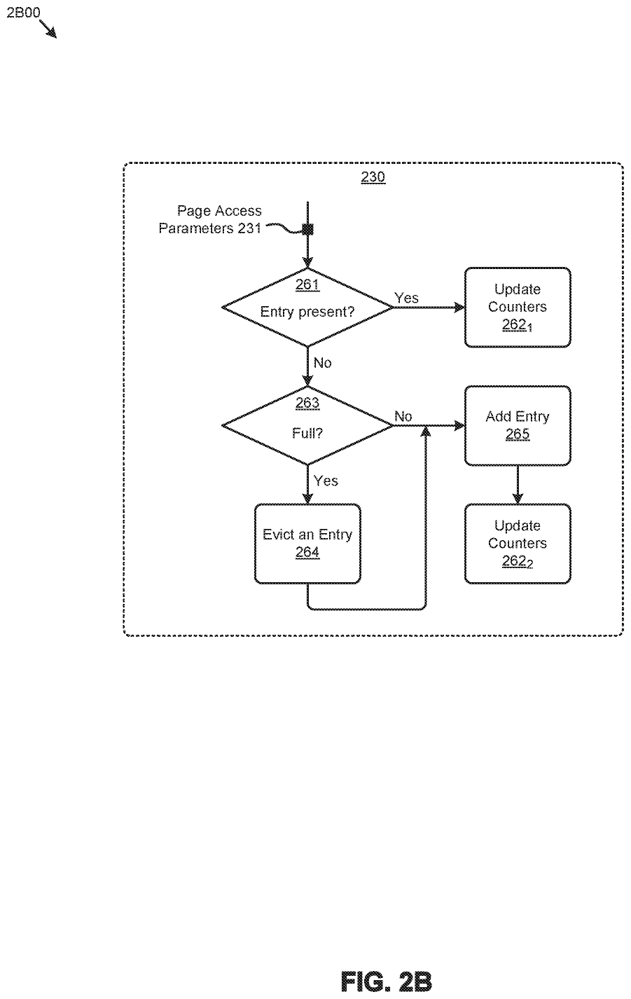

Variations of the foregoing flush processes as well as variations of paging operations that are to be performed over the multi-tiered memory system are further disclosed infra. Additionally, variations of processing page access events, including techniques for updating counters and other page access tracking techniques, are shown and discussed as pertains to FIG. 2A.

FIG. 2A depicts a hardware-assisted page access tracking technique 2A00 as implemented in systems that facilitate hardware-assisted page access tracking in multi-tiered random access memory systems. As an option, one or more variations of hardware-assisted page access tracking technique 2A00 or any aspect thereof may be implemented in the context of the architecture and functionality of the embodiments described herein. The hardware-assisted page access tracking technique 2A00 or any aspect thereof may be implemented in any environment.

The hardware-assisted page access tracking technique 2A00 presents one embodiment of certain steps and/or operations that facilitate hardware-assisted page access tracking in multi-tiered random access memory systems. As shown, certain portions of the steps and/or operations can be executed at a page access detector 110 as described herein.

The hardware-assisted page access tracking technique 2A00 can commence by identifying at least one random access memory device of a first type and at least one random access of a second type (e.g., a random access persistent memory device) in a computing system (step 205). The random access memory devices, possibly including any instances of random access persistent memory devices are configured to store data organized into pages (step 210). For example, the random access memory device might be configured as a primary random access memory space and the random access persistent memory device might be configured as a swap space.

During operation of the page access detector 110, page access events pertaining to the pages stored at the random access memory device and the random access persistent memory device are detected (step 220). Any form of logic (e.g., hardware-implemented logic, state machines, etc.) can be used to “snoop” or otherwise detect each page access event. In some cases, page accesses are determined based on the highest ordered bits of the address. For example, in a 64-bit memory subsystem, the highest-ordered 54 bits might be used to identify a particular page, whereas the lowest-ordered 10 bits are masked.

At step 230, one or more access counters corresponding to the pages are updated (e.g., incremented) in accordance with the detected page access events. For example, a “read” access event for a particular page might invoke an increment to a “read” access counter associated with the page. A page might also have a corresponding access counter to record a number of “writes” to the page, and/or a number of bytes accessed at the page, and/or a total number of accesses of the page. An access log is populated based at least in part on the values stored at the access counters (step 240). Various paging operations (e.g., page-in operations or page-out operations) are performed at the random access memory device and the random access persistent memory device based at least in part on the content of the access log (step 250). As time progresses (e.g., during the course of use of the CPU and the multi-tiered memory system), pages from the multiple memory tiers are maintained on an ongoing basis to achieve ongoing high performance.

FIG. 2B depicts a flowchart 2B00 that shows a portion of a hardware-assisted page access tracking technique as implemented in systems that facilitate hardware-assisted page access tracking in multi-tiered random access memory systems. As an option, one or more variations of the flows or any aspect thereof may be implemented in the context of the architecture and functionality of the embodiments described herein. Any portions of the flow or any aspect thereof may be implemented in any environment.

The flowchart depicts a technique for managing the contents of a CAM. Specifically, the shown flow commences upon receipt of a page access parameter 231. The page access parameter includes an address that is used as the base address of a page. At decision 261, the contents of the CAM are accessed to determine if the base address already exists in the CAM. If so, the “Yes” branch of decision 261 is taken and counters for that base address are updated at step 262₁ based at least in part on the value of the page access parameters.

If the base address does not exist in the CAM, then the “No” branch of decision 261 is taken and the CAM is checked (at decision 263) to determine if the CAM is full. If the CAM is full, step 264 then determines which entry to evict, and performs the eviction to make room to add a corresponding entry into the CAM (step 265). Counters corresponding to the added entry are updated (at step 262₂). If the CAM is not full, then an entry is added (step 265) and counters are initialized. The logic of flowchart 2B00 can be implemented as a state machine in logic 114. The logic of flowchart 2B00 can be implemented as a state machine such as is shown and described in FIG. 1B.

The foregoing techniques that enter a base address into a CAM as a key might use a base address that is formed by masking the lower-ordered 9 bits of the entire address of a memory word to form a base address at a 512-word memory address boundary. Other embodiments might mask the lower-ordered 10 bits of the entire address of a memory word to form a 1K memory word address boundary. Still other embodiments might mask the lower-ordered 12 bits of the entire address of a memory word to form a 4k memory word address boundary. In even still other embodiments, the number of masked bits is determined by a paging granularity index. For example, larger pages of 8K words or 16k words, etc. can be efficiently managed by masking off the lower 13 bits or 14 bits, etc. of a memory address.

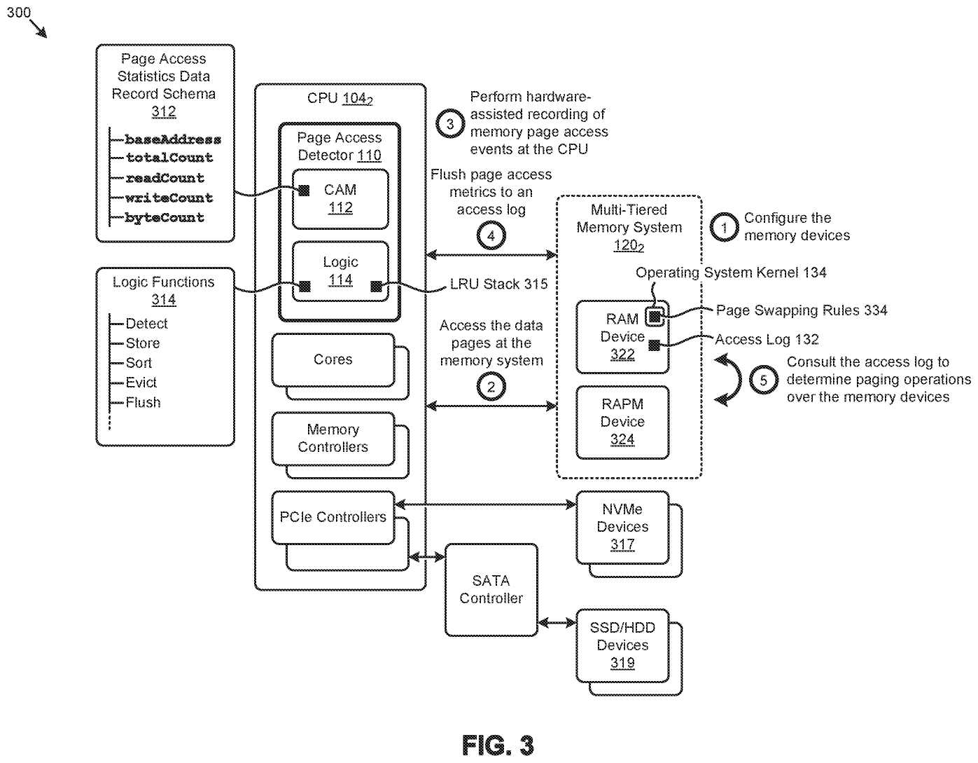

FIG. 3 presents a block diagram 300 of a system for hardware-assisted page access tracking in multi-tiered random access memory systems. As an option, one or more variations of block diagram 300 or any aspect thereof may be implemented in the context of the architecture and functionality of the embodiments described herein. The block diagram 300 or any aspect thereof may be implemented in any environment.

FIG. 3 illustrates one aspect pertaining to implementing a page access detector in a CPU of a computing system to accumulate page access statistics corresponding to a plurality of random access memory spaces of a multi-tiered memory system. Specifically, the figure is being presented to show one embodiment of the hardware components and associated data structures and data flows that facilitate hardware-assisted page access tracking in multi-tiered random access memory systems. The components, data structures, and data flows shown in FIG. 3 present one partitioning and associated data manipulation approach. The specific example shown is purely exemplary, and other subsystems, data structures, and/or partitioning are reasonable.

Specifically, the system of FIG. 3 presents an instance of CPU 104₂ and an instance of multi-tiered memory system 120₂ earlier described. In the shown embodiment, the multi-tiered memory system 120₂ comprises a RAM device 322 (e.g., a DDR4 DIMM) and an RAPM device 324 (e.g., an Intel Xpoint device). In this case, the RAM device 322 might be configured as the primary random access memory space and the RAPM device 324 might be configured as the swap space (operation 1). The cores and memory controllers at CPU 104₂ execute high-frequency accesses of the data pages at the multi-tiered memory system 120₂ (operation 2). In some cases, even though the RAPM device 324 is configured as a swap device, pages at the RAPM device 324 can be accessed directly by CPU 104₂ rather than swapping the page back into the RAM device 322 and then accessing the page at the RAM device 322. As the number and/or frequency of direct accesses at the RAPM device 324 by CPU 104₂ increases, however, the longer latencies of the RAPM device 324 as compared to that of the RAM device 322 will accumulate so as to favor swapping the accessed page or pages back from the RAPM device 324 to the RAM device 322 rather than continuing to access the frequently-accessed pages at the RAPM device 324.

To facilitate the high-frequency page access tracking in support of the foregoing paging between the RAPM device 324 and the RAM device 322, a page access detector 110 is implemented in CPU 104₂. The page access detector 110 performs hardware-assisted recording of memory page accesses at CPU 104₂ in accordance with the herein disclosed techniques (operation 3). In the shown embodiment, the page access detector 110 comprises an associative memory such as a content-addressable memory (e.g., the shown CAM 112) and a set of logic 114, each of which components are further discussed in the following paragraphs.

As for the associative memory, an associative memory differs from random access memory at least in that rather than responding to an address asserted on an address bus and producing a data value as a result, an associative memory responds to a given data value by producing the address where that data value is stored in the associative memory. Associative memories are often composed of a content-addressable memory (CAM). In some cases, such a CAM is combined with a RAM. A CAM is structurally different from a RAM, at least in that the memory bit cells of a CAM comprise both storage circuitry as well as comparison circuitry. Memory words in a CAM are arranged from such storage and comparison memory cells by laying out one cell adjacent to another (e.g., in a horizontal row), while leaving enough room in the layout for search lines and match lines. Multiple CAM memory words are arranged by laying out CAM memory words in an array (e.g., by laying out words in a vertical direction). Each storage and comparison cell has a connection to at least one match line that runs, for example, in a horizontal direction, and each cell has a connection to one or more search lines that run, for example, in a vertical direction.

The search lines that are routed to each cell serve to broadcast “content” to be matched to a word in a row. If there is a match between the broadcasted content and the content of the word of the CAM, then the match line of that word will be activated. The address of that word is then delivered to the CAM output as a match address. A CAM that matches on a longer bit length of content can be formed by using more cells in the CAM memory word. A larger and larger number of unique occurrences of content can be accommodated by adding more and more CAM memory words to the array.

This CAM architecture is distinguished from a RAM memory that includes a state machine or other lookup mechanism, at least in that a RAM memory does not contain match lines and search lines that are interconnected to each cell of a memory word. Also, the CAM performance is different from performance of a RAM memory that includes a state machine or other lookup mechanism, at least because a CAM implementation performs matching to compare the input content across all words of the CAM in parallel, whereas a RAM memory that includes a state machine or other lookup mechanism performs matching through successive comparisons.

As for the logic 114, such logic can comprise hardware logic (e.g., CMOS logic circuits) designed to carry out certain functions. Specifically, and as shown in the set of logic functions 314, logic 114 might be designed to “detect” page access events (e.g., detect page access instructions at CPU 104₂), “store” page access statistics (e.g., update access counters at CAM 112), maintain a finite-sized LRU stack 315 (e.g., according to an LRU scheme), “sort” the data records of CAM 112 (e.g., by managing pointers), “evict” data records from CAM 112 (e.g., evict the data record of the least recently accessed page), “flush” all data records from CAM 112 (e.g., flush every one second according to a flush schedule), and/or other perform other functions.

The CAM 112 comprises a memory structure that facilitates high-speed content access. Many types of memory structures and other hardware can be combined to facilitate high-speed content access. In some embodiments an associative memory comprises one or more associative arrays formed of CAM storage and comparison memory cells that are interconnected to search and match lines in a manner as earlier described. Content addressable memory structures are often configured to identify stored content (e.g., data records) for a data word and, if the data word is found, perform some associated operation (e.g., return the address and/or data associated with the data word). To facilitate the herein disclosed techniques, CAM 112 might be structured and/or organized in accordance with a page access statistics data record schema 312. Specifically, according to the page access statistics data record schema 312, each data record in CAM 112 might have a key comprising the “baseAddress” of a particular page and one or more access counters associated with the key (e.g., a total access count stored in a “totalCount” field, a “read” count stored in a “readCount” field, a “write” count stored in a “writeCount” field, and a byte count stored in a “byteCount” field). In this case, the base address (e.g., the upper N bits of the page address) of the accessed page is used as the key to limit the size of the CAM 112.

Since the page access statistics data records of CAM 112 are not accessible by an operating system so as to facilitate paging operations, the data records of CAM 112 are evicted and/or flushed to an access log 132 from time to time (operation 4). As can be observed, access log 132 might be stored at RAM device 322 in a structure that can be accessed by the operating system kernel 134. As such, certain page swapping rules 334 at the operation system kernel 134 can be applied to the data records of the access log 132 to perform various paging operations (e.g., swap in, swap out, etc.) over the multi-tiered memory system (operation 5).

In some cases, a computing system might include NVMe devices 317 and/or SSD/HDD devices 319, any of which can be interfaced with corresponding PCIe controllers 321. In addition to the aforementioned paging operations that are performed over the multi-tiered memory system, certain paging operations can be performed over the NVMe and/or SSD/HDD devices.

In addition to presenting an embodiment of a computing system, the foregoing discussions describe techniques for evicting page access statistics data records to an access log, which techniques are disclosed in further detail as follows.

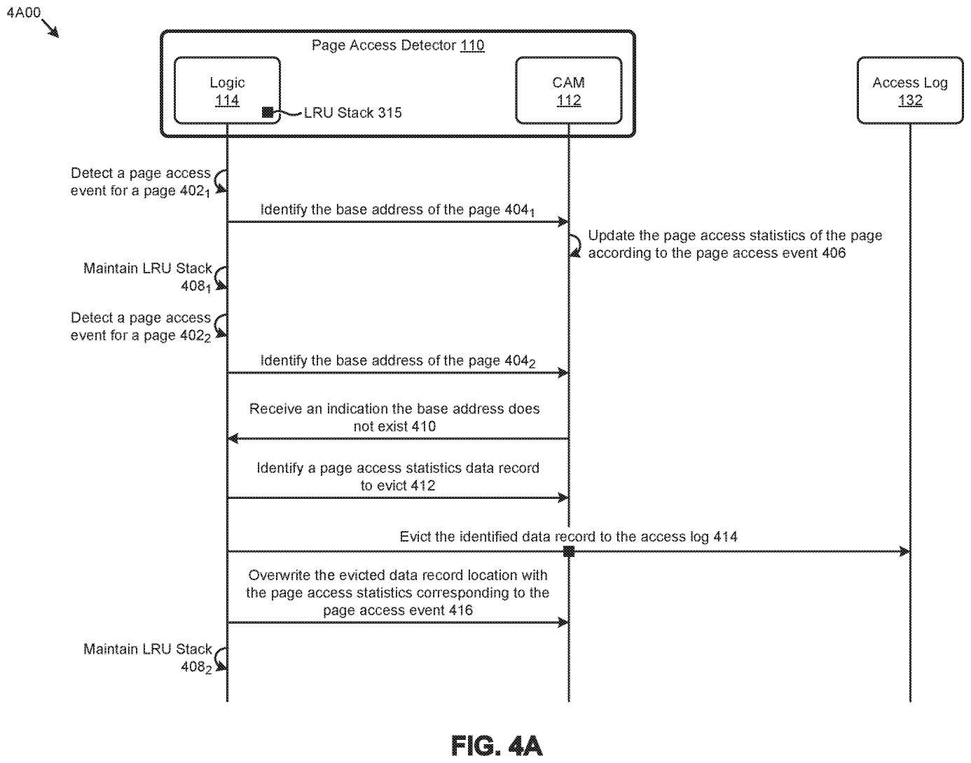

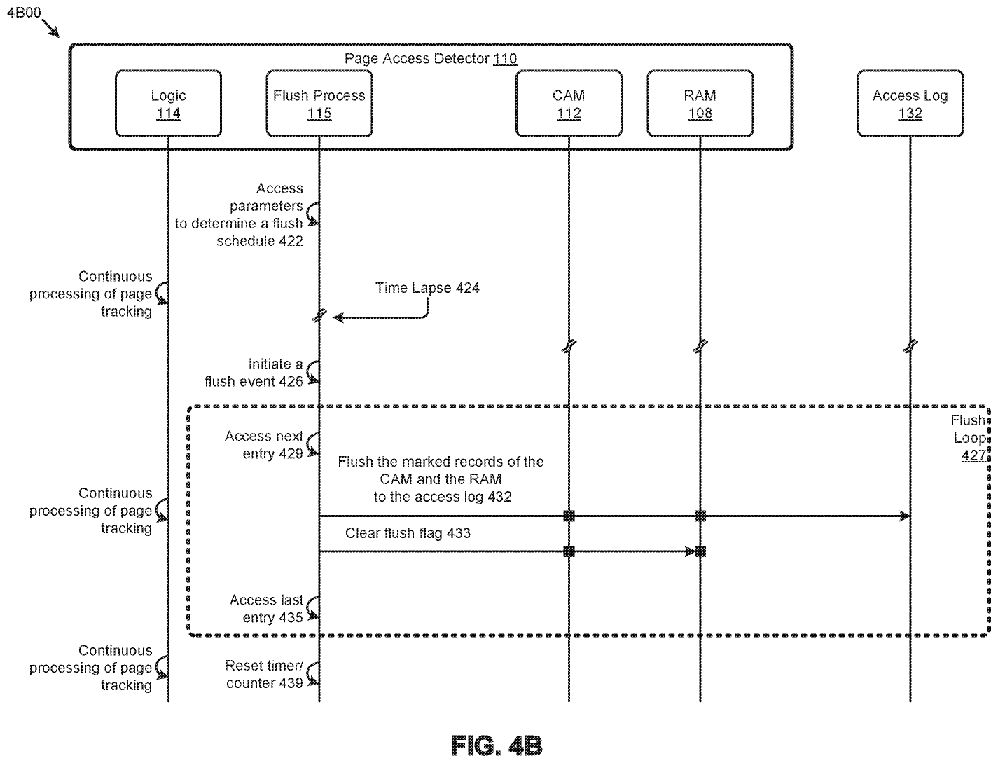

FIG. 4A depicts a page access statistics eviction technique 4A00 as implemented in systems that facilitate hardware-assisted page access tracking in multi-tiered random access memory systems. As an option, one or more variations of page access statistics eviction technique 4A00 or any aspect thereof may be implemented in the context of the architecture and functionality of the embodiments described herein. The page access statistics eviction technique 4A00 or any aspect thereof may be implemented in any environment.

FIG. 4A illustrates one aspect pertaining to implementing a page access detector in a CPU of a computing system to accumulate page access statistics corresponding to a plurality of random access memory spaces of a multi-tiered memory system. Specifically, the figure is being presented with respect to its contribution to managing (e.g., evicting) the data records storing the page access statistics so as to control the size of the memory (e.g., CAM, associative array, etc.) that stores the data records. The page access statistics eviction technique 4A00 shown in FIG. 4A depicts various computing system components earlier described that can exhibit a set of high order interactions (e.g., operations, messages, etc.) to facilitate such data record management.

Specifically shown are logic 114 and CAM 112 of the page access detector 110 and the access log 132. In this embodiment, the depicted logic 114 includes an LRU stack. During the course of operation of the page access statistics eviction technique 4A00, the contents of the LRU stack are manipulated for compactness and/or for sorting/ordering. The page access statistics eviction technique 4A00 can commence with the logic 114 detecting a page access event for a page (operation 402₁). The logic 114 accesses the CAM 112 to identify the base address of the page (message 404₁). If the base address is found at CAM 112, the page access statistics (e.g., access count, read count, write count, byte count, etc.) of the of the page are updated in accordance with the detected page access event (operation 406). The logic 114 might then manipulate the LRU stack and/or any portions of the page access statistics data records at CAM 112 (maintenance operation 408₁).

When another page access event is detected (operation 402₂), identification of the base address of the page is invoked (message 404₂). In this case, however, an indication that the base address is not present at CAM 112 is received at logic 114 (message 410). The logic 114 identifies a page access statistics data record to evict from CAM 112 (message 412). For example, if the data records of CAM 112 are sorted according to an LRU technique, the data record at the top (or bottom) of CAM 112 might correspond to the least recently accessed page or pages (e.g., the page base address with the lowest access count), which data record can be identified for eviction. The identified data record can be evicted from CAM 112 by writing the content of the data record to access log 132 (message 414). The evicted data record location at CAM 112 is then overwritten with the page access statistics corresponding to the detected page access event (message 416). The logic 114 can again manipulate the LRU stack and/or any portions of the page access statistics data records at CAM 112 (management message 408₂).

The discussions herein also include techniques for flushing page access statistics data records to an access log, which techniques are disclosed in further detail as follows.

FIG. 4B depicts a page access statistics flush technique 4B00 as implemented in systems that facilitate hardware-assisted page access tracking in multi-tiered random access memory systems. As an option, one or more variations of page access statistics flush technique 4B00 or any aspect thereof may be implemented in the context of the architecture and functionality of the embodiments described herein. The page access statistics flush technique 4B00 or any aspect thereof may be implemented in any environment.

FIG. 4B illustrates one aspect pertaining to implementing a page access detector in a CPU of a computing system to accumulate page access statistics corresponding to a plurality of random access memory spaces of a multi-tiered memory system. Specifically, the figure is being presented with respect to its contribution to managing (e.g., flushing) the data records storing the page access statistics so as to timely process pages and to control the contents of the memory or other storage devices (e.g., CAM, associative arrays, shift registers, register file, random access memory, etc.) that stores the page access statistics. The page access statistics flush technique 4B00 shown in FIG. 4B depicts various computing system components earlier described that can exhibit a set of high order interactions (e.g., operations, messages, etc.) to facilitate uses of page access statistics.

Specifically shown are interactions between the flush process 115, CAM 112, random access memory 108 of the page access detector 110, and the access log 132. The page access statistics flush technique 4B00 can commence when the flush process 115 accesses schedule parameters that determine a flush schedule for CAM 112 and random access memory 108 (operation 422). Such schedule parameters might include a flush time period value (e.g., 1 second) that is established by a system administrator in a BIOS setup. After a time lapse 424 (e.g., 1 second, in accordance with an established flush period), the flush process 115 might initiate a CAM flush event (operation 426). Initiation of such a CAM flush event results in proceeding into the shown flush loop 427. The flush process 115 iterates in this loop to access the CAM/RAM from a first entry (at operation 429), and continuing through successive individual entries of the CAM/RAM to determine (at operation 432) if the flush flag is set for the particular individual entry of the then-current iteration and, if so, to flush the particular individual entry to the access log 132. At operation 433, the flush flag of the entry of the then-current iteration is cleared. The loop continues through encountering the last entry to be iterated over (at operation 435). The loop exits and the flush process resets its timer/counter (operation 421). In some cases, the bounds of the flush loop are determined by the number and/or locations of entries in the CAM.

During the processing of flush process 115 (e.g., during the processing from operation 422 through operation 439), logic 114 continues to process page tracking. In some cases, a dual-port RAM is used to implement random access memory 108.

The foregoing discussions describe techniques for processing of high frequency page tracking events concurrent with periodic flushing of data records (e.g., counters and timestamps) to the access log. Various uses of the access log are disclosed in detail as follows.

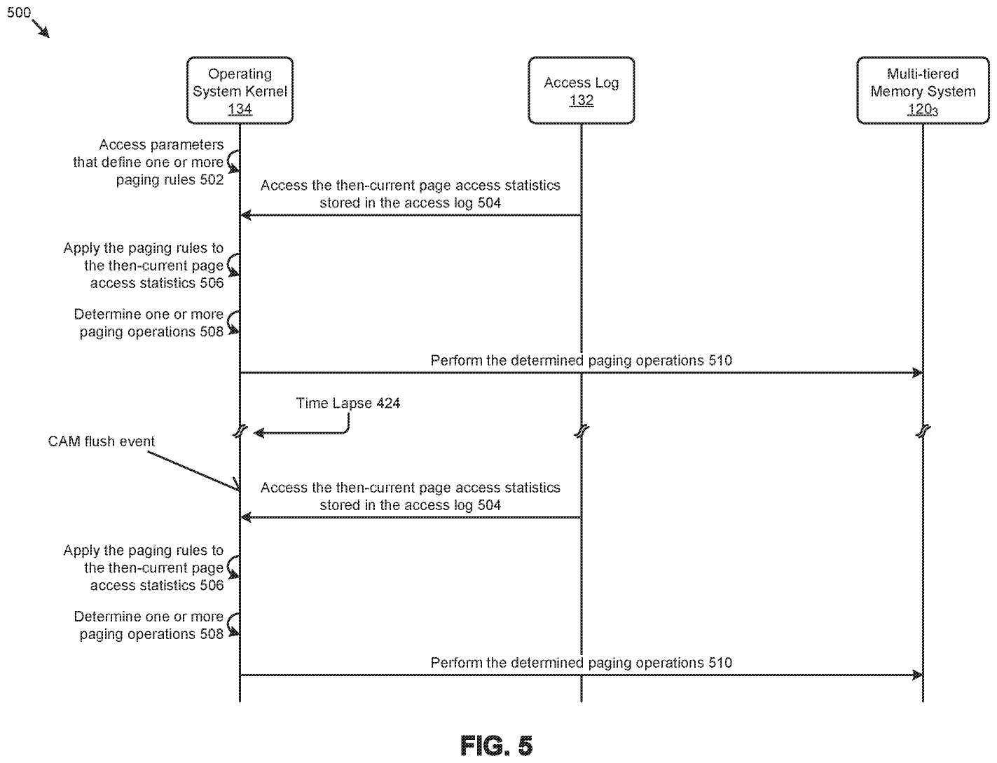

FIG. 5 illustrates a paging technique 500 as implemented in systems that facilitate hardware-assisted page access tracking in multi-tiered random access memory systems. As an option, one or more variations of paging technique 500 or any aspect thereof may be implemented in the context of the architecture and functionality of the embodiments described herein. The paging technique 500 or any aspect thereof may be implemented in any environment.

FIG. 5 illustrates one aspect pertaining to implementing a page access detector in a CPU of a computing system to accumulate page access statistics corresponding to a plurality of random access memory spaces of a multi-tiered memory system. Specifically, the figure is being presented with respect to its contribution to performing paging operations over the multi-tiered memory system based at least in part on the page access statistics. The paging technique 500 shown in FIG. 5 depicts various computing system components earlier described that can exhibit a set of high order interactions (e.g., operations, messages, etc.) to facilitate such paging operations.

Specifically shown are the operating system kernel 134, the access log 132, and an instance of the multi-tiered memory system 120₃. The paging technique 500 can commence with the operating system kernel 134 accessing parameters that define one or more paging rules (operation 502). For example, such parameters might include a page access count threshold above which a respective page is to be swapped to a higher-tiered memory device (e.g., from an RAPM swap device to a RAM device). The operating system kernel 134 accesses the then-current page access statistics stored in the access log 132 (message 504). As an example, according the herein disclosed techniques, the access log 132 is populated from data records evicted and/or flushed from a CAM or other memory structure of a page access detector. The operating system kernel 134 can apply the paging rules to the then-current page access statistics from the access log (operation 506) to determine one or more paging operations (operation 508). For example, the aforementioned page access count threshold can be applied to the access counts from the access log 132 to determine which pages, if any, are to be swapped to a higher or highest performance memory in the multi-tiered memory system 120₃. The operating system kernel 134 can then perform the paging operations at the multi-tiered memory system 120₃ (message 510).

The foregoing process can be repeated any number of times during operation of the CPU. Specifically, and as shown, after a time lapse 424, the end of which time lapse might correspond to a CAM flush event, another message 504, and another invocation of operation 506, and another invocation of operation 508, and another invocation of message 510 can be processed in observance of the paging rules that were accessed in operation 502. Thus, pages from the multiple memory tiers are maintained on an ongoing basis to achieve ongoing high performance of the computing platform.

### Additional Embodiments Of the Disclosure

### Additional Practical Application Examples

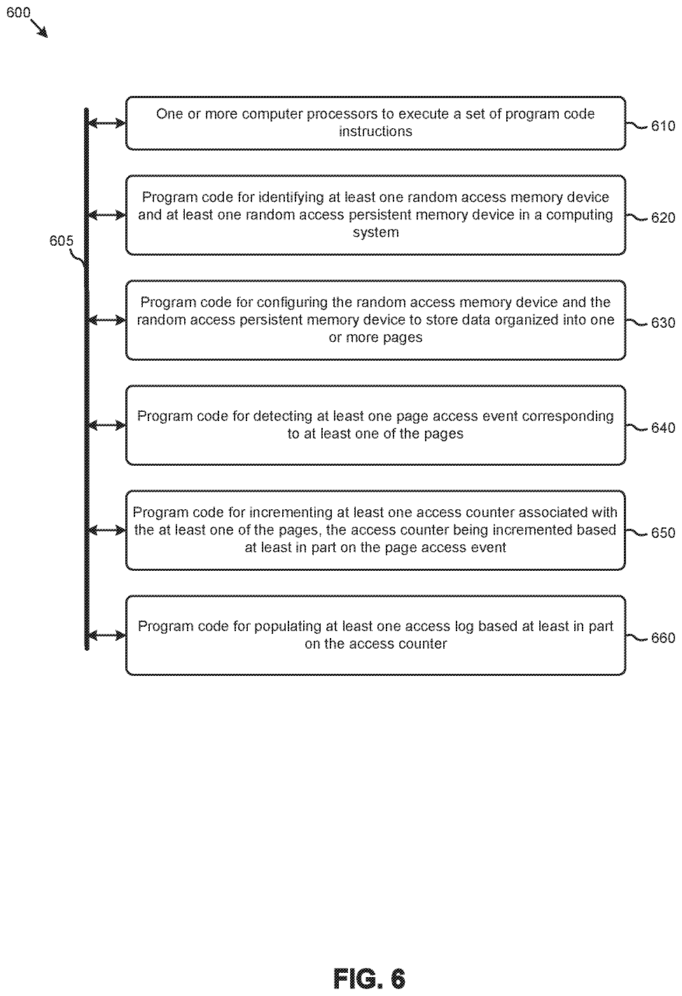

FIG. 6 depicts a system 600 as an arrangement of computing modules that are interconnected so as to operate cooperatively to implement certain of the herein-disclosed embodiments. This and other embodiments present particular arrangements of elements that, individually and/or as combined, serve to form improved technological processes that address page access tracking in multi-tiered random access memory systems. The partitioning of system 600 is merely illustrative and other partitions are possible. As an option, the system 600 may be implemented in the context of the architecture and functionality of the embodiments described herein. Of course, however, the system 600 or any operation therein may be carried out in any desired environment.

The system 600 comprises at least one processor and at least one memory, the memory serving to store program instructions corresponding to the operations of the system. As shown, an operation can be implemented in whole or in part using program instructions accessible by a module. The modules are connected to a communication path 605, and any operation can communicate with other operations over communication path 605. The modules of the system can, individually or in combination, perform method operations within system 600. Any operations performed within system 600 may be performed in any order unless as may be specified in the claims.

The shown embodiment implements a portion of a computer system, presented as system 600, comprising one or more computer processors and/or hardware logic to execute a set of program code instructions or microcode (module 610) and modules for accessing memory to hold program code instructions or microcode to perform: identifying at least one random access memory device and at least one random access persistent memory device in a computing system (module 620); configuring the random access memory device and the random access persistent memory device to store data organized into one or more pages (module 630); detecting at least one page access event corresponding to at least one of the pages (module 640); incrementing at least one access counter associated with the at least one of the pages, the access counter being incremented based at least in part on the page access event (module 650); and populating at least one access log based at least in part on the access counter (module 660).

Variations of the foregoing may include more or fewer of the shown modules. Certain variations may perform more or fewer (or different) steps and/or certain variations may use data elements in more or in fewer (or different) operations. Strictly as example embodiments, variations include steps for performing one or more paging operations, the one or more paging operations being based at least in part on one or more data records comprising the access log. Still further variations include steps wherein the paging operations perform at least one of, a first swapping of at least one of the pages from the random access persistent memory device to the random access memory device, or a second swapping of at least one of the pages from the random access memory device to the random access persistent memory device.

Other embodiments comprise steps for sorting a plurality of page access statistics data records, at least one of the page access statistics data records comprising an access counter. Other embodiments include variations wherein the page access statistics data records are sorted based at least in part on an LRU algorithm. Still other embodiments include steps for evicting at least one of the page access statistics data records to the access log, and/or steps for flushing the page access statistics data records to the access log.

### System Architecture Overview

### Additional System Architecture Examples

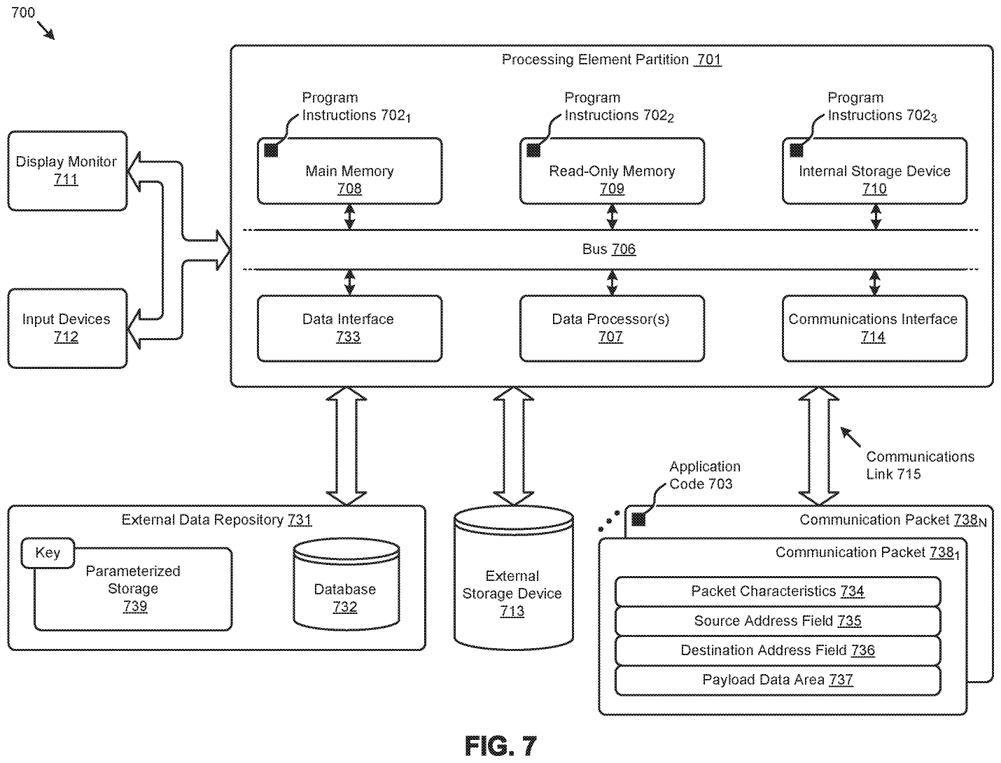

FIG. 7 depicts a block diagram of an instance of a computer system 700 suitable for implementing embodiments of the present disclosure. Computer system 700 includes a bus 706 or other communication mechanism for communicating information. The bus interconnects subsystems and devices such as a central processing unit (CPU), or a multi-core CPU (e.g., data processor 707), a system memory (e.g., main memory 708, or an area of random access memory (RAM)), a non-volatile storage device or non-volatile storage area (e.g., read-only memory 709), an internal storage device 710 or external storage device 713 (e.g., magnetic or optical), a data interface 733, a communications interface 714 (e.g., PHY, MAC, Ethernet interface, modem, etc.). The aforementioned components are shown within processing element partition 701, however other partitions are possible. Computer system 700 further comprises a display 711 (e.g., CRT or LCD), various input devices 712 (e.g., keyboard, cursor control), and an external data repository 731.

According to an embodiment of the disclosure, computer system 700 performs specific operations by data processor 707 executing one or more sequences of one or more program code instructions contained in a memory. Such instructions (e.g., program instructions 702₁, program instructions 702₂, program instructions 702₃, etc.) can be contained in or can be read into a storage location or memory from any computer readable/usable storage medium such as a static storage device or a disk drive. The sequences can be organized to be accessed by one or more processing entities configured to execute a single process or configured to execute multiple concurrent processes to perform work. A processing entity can be hardware-based (e.g., involving one or more cores) or software-based, and/or can be formed using a combination of hardware and software that implements logic, and/or can carry out computations and/or processing steps using one or more processes and/or one or more tasks and/or one or more threads or any combination thereof.

According to an embodiment of the disclosure, computer system 700 performs specific networking operations using one or more instances of communications interface 714. Instances of communications interface 714 may comprise one or more networking ports that are configurable (e.g., pertaining to speed, protocol, physical layer characteristics, media access characteristics, etc.) and any particular instance of communications interface 714 or port thereto can be configured differently from any other particular instance. Portions of a communication protocol can be carried out in whole or in part by any instance of communications interface 714, and data (e.g., packets, data structures, bit fields, etc.) can be positioned in storage locations within communications interface 714, or within system memory, and such data can be accessed (e.g., using random access addressing, or using direct memory access DMA, etc.) by devices such as data processor 707.

Communications link 715 can be configured to transmit (e.g., send, receive, signal, etc.) any types of communications packets (e.g., communication packet 738₁, communication packet 738_{N}) comprising any organization of data items. The data items can comprise a payload data area 737, a destination address 736 (e.g., a destination IP address), a source address 735 (e.g., a source IP address), and can include various encodings or formatting of bit fields to populate packet characteristics 734. In some cases, the packet characteristics include a version identifier, a packet or payload length, a traffic class, a flow label, etc. In some cases, payload data area 737 comprises a data structure that is encoded and/or formatted to fit into byte or word boundaries of the packet.

In some embodiments, hard-wired circuitry may be used in place of or in combination with software instructions to implement aspects of the disclosure. Thus, embodiments of the disclosure are not limited to any specific combination of hardware circuitry and/or software. In embodiments, the term “logic” shall mean any combination of software or hardware that is used to implement all or part of the disclosure.

The term “computer readable medium” or “computer usable medium” as used herein refers to any medium that participates in providing instructions to data processor 707 for execution. Such a medium may take many forms including, but not limited to, non-volatile media and volatile media. Non-volatile media includes, for example, optical or magnetic disks such as disk drives or tape drives. Volatile media includes dynamic memory such as RAM.

Common forms of computer readable media include, for example, floppy disk, flexible disk, hard disk, magnetic tape, or any other magnetic medium; CD-ROM or any other optical medium; punch cards, paper tape, or any other physical medium with patterns of holes; RAM, PROM, EPROM, FLASH-EPROM, or any other memory chip or cartridge, or any other non-transitory computer readable medium. Such data can be stored, for example, in any form of external data repository 731, which in turn can be formatted into any one or more storage areas, and which can comprise parameterized storage 739 accessible by a key (e.g., filename, table name, block address, offset address, etc.).

Execution of the sequences of instructions to practice certain embodiments of the disclosure are performed by a single instance of a computer system 700. According to certain embodiments of the disclosure, two or more instances of computer system 700 coupled by a communications link 715 (e.g., LAN, public switched telephone network, or wireless network) may perform the sequence of instructions required to practice embodiments of the disclosure using two or more instances of components of computer system 700.

Computer system 700 may transmit and receive messages such as data and/or instructions organized into a data structure (e.g., communications packets). The data structure can include program instructions (e.g., application code 703), communicated through communications link 715 and communications interface 714. Received program code may be executed by data processor 707 as it is received and/or stored in the shown storage device or in or upon any other non-volatile storage for later execution. Computer system 700 may communicate through a data interface 733 to a database 732 on an external data repository 731. Data items in a database can be accessed using a primary key (e.g., a relational database primary key).

Processing element partition 701 is merely one sample partition. Other partitions can include multiple data processors, and/or multiple communications interfaces, and/or multiple storage devices, etc. within a partition. For example, a partition can bound a multi-core processor (e.g., possibly including embedded or co-located memory), or a partition can bound a computing cluster having plurality of computing elements, any of which computing elements are connected directly or indirectly to a communications link. A first partition can be configured to communicate to a second partition. A particular first partition and particular second partition can be congruent (e.g., in a processing element array) or can be different (e.g., comprising disjoint sets of components).

A module as used herein can be implemented using any mix of any portions of the system memory and any extent of hard-wired circuitry including hard-wired circuitry embodied as a data processor 707. Some embodiments include one or more special-purpose hardware components (e.g., power control, logic, sensors, transducers, etc.). Some embodiments of a module include instructions that are stored in a memory for execution so as to facilitate operational and/or performance characteristics pertaining to hardware-assisted page access tracking in multi-tiered random access memory systems. A module may include one or more state machines and/or combinational logic used to implement or facilitate the operational and/or performance characteristics pertaining to hardware-assisted page access tracking in multi-tiered random access memory systems.

Various implementations of database 732 comprise storage media organized to hold a series of records or files such that individual records or files are accessed using a name or key (e.g., a primary key or a combination of keys and/or query clauses). Such files or records can be organized into one or more data structures (e.g., data structures used to implement access logs and/or to facilitate aspects of hardware-assisted page access tracking in multi-tiered random access memory systems). Such files, records, logs, or any such data structures can be brought into and/or stored in volatile or non-volatile memory. More specifically, the occurrence and organization of the foregoing files, records, logs and other data structures improve the way that the computer stores and retrieves data in memory, for example, to improve the way data is accessed when the computer is performing operations pertaining to hardware-assisted page access tracking in multi-tiered random access memory systems, and/or for improving the way data is manipulated when performing computerized operations pertaining to implementing a page access detector in a CPU of a computing system to accumulate page access statistics corresponding to a plurality of random access memory spaces of a multi-tiered memory system.

In the foregoing specification, the disclosure has been described with reference to specific embodiments thereof. It will however be evident that various modifications and changes may be made thereto without departing from the broader spirit and scope of the disclosure. For example, the above-described process flows are described with reference to a particular ordering of process actions. However, the ordering of many of the described process actions may be changed without affecting the scope or operation of the disclosure. The specification and drawings are to be regarded in an illustrative sense rather than in a restrictive sense.

1. A system comprising:
a first tier of a multi-tiered memory system, the first tier comprising a first memory device having a first performance characteristic;
a second tier of the multi-tiered memory system, the second tier comprising a second memory device having a second performance characteristic that is different from the first performance characteristic;
a CPU that tracks a page of memory accessed by the CPU using an associative memory that stores:
a memory address that is used to access the page of memory by the CPU at the first memory device or the second memory device, and
a count that is associated to the memory address, wherein the count corresponds to an access count of the page of memory; and
a logic block of the CPU that updates a memory structure that corresponds to the access count of the page of memory, wherein the page of memory is swapped from the second tier to the first tier when the count is above an access count threshold.

2. The system of claim 1, wherein the associative memory comprises a content addressable memory.

3. The system of claim 2, wherein the content addressable memory comprises a plurality of cells that comprise both storage circuitry and comparison circuitry.

4. The system of claim 2, wherein the associative memory further comprises a random access memory interfaced to the content addressable memory.

5. The system of claim 1, wherein the first memory device is a DRAM device having a first speed and the second memory device is a RAPM device.

6. The system of claim 1, wherein the first memory device is a first DRAM device having of a first speed and the second memory device is a second DRAM device having a second speed.

7. The system of claim 1, wherein the memory address comprises an address portion that is at a 512-word address boundary, or a 1K word address boundary, or a 4k word address boundary.

8. The system of claim 1, wherein the memory structure comprises one or more access counters.

9. The system of claim 8, wherein the one or more access counters comprise one or more read counters, or one or more write counters, or one or more transfer counters.

10. The system of claim 1, wherein the logic block responds to a flush signal.

11. A method for comprising:
configuring a multi-tiered memory system comprising:
a first tier of the multi-tiered memory system, the first tier comprising a first memory device having a first performance characteristic; and
a second tier of the multi-tiered memory system, the second tier comprising a second memory device having a second performance characteristic that is are different from the first performance characteristic;
tracking, via a CPU, a page of memory accessed by the CPU by configuring an associative memory that stores:
a memory address that is used to access the page of memory by the CPU at the first memory device or the second memory device, and
a count that is associated to the memory address, wherein the count corresponds to an access count of the page of memory; and
updating, via a logic block in the CPU, a memory structure that corresponds to the access count of the page of memory, wherein the page of memory is swapped from the second tier to the first tier when the count is above an access count threshold.

12. The method of claim 11, wherein the associative memory comprises a content addressable memory.

13. The method of claim 12, wherein the associative memory further comprises a random access memory interfaced to the content addressable memory.

14. The method of claim 13, wherein an output of the content addressable memory is interfaced to an input of the random access memory.

15. The computer readable medium of claim 21, wherein the first memory device is a DRAM device having a first speed and the second memory device is a RAPM device.

16. The computer readable medium of claim 21, wherein the first memory device is a first DRAM device having of a first speed and the second memory device is a second DRAM device having a second speed.

17. The computer readable medium of claim 21, wherein the memory address comprises an address portion that is at a 512 word address boundary, or a 1K word address boundary, or a 4k word address boundary.

18. The computer readable medium of claim 21, wherein the memory structure comprises one or more access counters.

19. The computer readable medium of claim 18, wherein the one or more access counters comprise one or more read counters, or one or more write counters, or one or more transfer counters.

20. The method of claim 11, wherein the logic block responds to a flush signal.

21. A computer readable medium, embodied in a non-transitory computer readable medium, the non-transitory computer readable medium having stored thereon a sequence of instructions which, when stored in memory and executed by one or more processors causes the one or more processors to perform a set of acts, the set of acts comprising:
configuring a multi-tiered memory system comprising:
a first tier of the multi-tiered memory system, the first tier comprising a first memory device having a first performance characteristic, and
a second tier of the multi-tiered memory system, the second tier comprising a second memory device having a second performance characteristic that is different from the first performance characteristic;
tracking, via a CPU, a page of memory accessed by the CPU by configuring an associative memory that stores:
a memory address that is used to access the page of memory by the CPU at the first memory device or the second memory device, and
a count that is associated to the memory address, wherein the count corresponds to an access count of the page of memory; and
updating, via a logic block in the CPU, a memory structure that corresponds to the access count of the page of memory, wherein the page of memory is swapped from the second tier to the first tier when the count is above an access count threshold.

22. The computer readable medium of claim 21, wherein the associative memory comprises a content addressable memory.

23. The computer readable medium of claim 22, wherein the content addressable memory comprises a plurality of cells that comprise both storage circuitry and comparison circuitry.

24. The computer readable medium of claim 22, wherein the associative memory further comprises a random access memory interfaced to the content addressable memory.
